(19) United States
(12) Patent Application Publication
(10) Pub. No.: US 2001/0027008 A1
(43) Pub. Date: Oct. 4, 2001

(54) Method for forming interconnect structure in semiconductor device

(76) Inventor: Akira Matsumoto, Tokyo (JP)

Correspondence Address: YOUNG & THOMPSON, 745 SOUTH 23RD STREET 2ND FLOOR, ARLINGTON, VA, 22202

(21) Appl. No.: 09/775,605

(22) Filed: Feb. 5, 2001

(30) Foreign Application Priority Data
Feb. 4, 2000 (JP) 2000-28393

(51) Int. Cl. H01L 21/4763

(52) U.S. Cl. 438/618

(57) ABSTRACT

A method of fabricating a semiconductor device including the steps of: forming a first trench and a second trench having a width larger than a width of the first trench in a dielectric film, and simultaneously a slit pattern at a central portion of the second trench; depositing a conductive layer on the dielectric film; and polishing the conductive layer until a surface of the dielectric film is exposed to leave the conductive layer in the first and the second trenches and the slit pattern, thereby forming a damascene interconnect structure on the surface of the dielectric layer. In accordance with the present invention, the formation of the slit pattern formed on the central portion of the larger width trench can increase the thickness of the plated film, thereby suppressing the dishing of the plated film on the central portion of the larger width interconnect.

### BACKGROUND OF THE INVENTION

(a) Field of the Invention

The present invention relates to a method for forming an interconnect structure in a semiconductor device, especially to the method for forming the interconnect structure in which dishing and erosion are reduced.

(b) Description of the Related Art

The development of the interconnect structure with smaller dimensions is necessary for achieving the higher integration in the semiconductor device. As a method for forming such an interconnect structure, a so-called damascene technology or wiring trench technique is investigated which forms trenches in a dielectric film overlying a semiconductor substrate and fills the trenches with a conductive material.

In the damascene technology, as shown in FIG. 1A, after a dielectric film 12 such as a silicon dioxide (SiO₂) film is formed overlying a semiconductor substrate 11 having device elements (not shown), smaller width trenches 13 for receiving thereon interconnects and a larger width trench 15 for receiving a pad are formed in the dielectric film 12 by using a conventional method for exposure and anisotropic dry etching technology. The width and the depth of the smaller width trenches 13 are, for example, between 0.2 and 0.5 μm, and about 0.5 μm, respectively. The larger width trench 15 is of a square having a side of about 100 μm and a depth of 0.5 μm.

Subsequently, as shown in FIG. 1B, a Ti film 16 and a TiN film 17 are sequentially deposited, in a higher vacuum ambient, on the dielectric film 12 having the smaller width trenches 13 and the larger width trench 15 to form an underlying barrier metal film by using a magnetron sputtering method. An Al alloy film 18 made of an interconnect material, for example, Al-0.5%Cu is deposited on the entire surface of the barrier metal film by using the DC magnetron sputtering method in a higher vacuum ambient. The semiconductor substrate 11 is heated up to the melting point of the Al alloy in a pressurized and highly evacuated re-flow chamber to melt or soften the Al alloy film 18. Under the circumstances, a highly pressurized inert gas such as argon (Ar) is introduced to the re-flow chamber, thereby completely filling the interior of the smaller width trenches 13 and the larger width trench 15 with the Al alloy film 18.

Thereafter, the Al alloy film 18 and the barrier metal film are polished until the top surface of the dielectric film 12 is exposed to remove portions of the Al alloy film 18 and the barrier metal film (TiN film 17 and Ti film 16) formed other than in the smaller width trenches 13 and the larger width trench 15. Thereby, as shown in FIG. 1C, damascene interconnects 19 and 20 are formed in the smaller width trenches 13 and the larger width trench 15, respectively.

The conventional method as described above includes the following problems.

When the Al alloy film 18 is polished, the central top surface of the damascene interconnect 20 of the larger width trench 15 is removed to reduce the level of the central top surface downward. The problem is referred to as dishing and exerts an inverse influence against the succeeding planarization step or a wire bonding step during the assembly. Further, in the conventional technique, erosion is likely to occur at the time of the CMP in the area where a large number of smaller width trenches are disposed.

JP-A-11(1999)-165253 describes a method for solving the dishing problem in the larger width trenches during the CMP step. In the technique described herein, after a barrier metal film (TiN film) and a Cu film are deposited, the Cu film is subjected to re-flown thereof. Then, the CMP using slurry containing copper ions is conducted. Thereafter, the Cu film is subjected to the CMP with a negative potential applied thereto, thereby preventing the dishing problem in of the Cu film in the larger width trenches. The CMP of the Cu film by using the slurry containing the copper ions electrically plates the Cu film having the dishing with another Cu film, thereby reinforcing the dished portion of the Cu film to some extent.

However, in the technique, the CMP conducted concurrently with the electroplating of the Cu film contaminates the Cu film deposited by the electroplating with an abrasive material and hardly controls the thickness of the Cu film deposited by the electroplating.

### SUMMARY OF THE INVENTION

In view of the foregoing, an object of the present invention is to provide a method for forming an interconnect structure in a semiconductor device in which an interconnect pad or an interconnect required to have a larger width prevents dishing generated by CMP and erosion in a section having a densely deposited interconnect region, and the semiconductor device can be fabricated with a higher yield.

Thus, the present invention provides a method for fabricating a semiconductor device including the steps of: forming a first trench and a second trench in a surface of a dielectric film, the second trench having a width larger than a width of the first trench and having therein a slit wall extending along the second trench on a bottom of the second trench: depositing a conductive layer on the dielectric film including the first and second trenches; and polishing the conductive layer until a surface of the dielectric film is exposed, to leave the conductive layer in the first and second trenches as interconnect layers.

In the present invention, a trench pattern having a depth larger than that of the first trench at a central portion of the second trench may be formed before the formation of the second trench.

Further, in the present invention, a plurality of dummy trenches may be formed, in place of the second trench, on an open region on which no interconnects are formed or the density thereof is low.

In accordance with the present invention, the formation of the slit pattern or the trench pattern formed on the central portion of the larger width trench can increase the thickness of the plated film, thereby suppressing the dishing of the plated film on the central portion of the larger width interconnect duo to the CMP. When another dielectric film is formed thereon followed by perforation of via-holes, the connecting deficiency of the via-holes to the larger width interconnect due to the excessive thickness of the underlying dielectric film can be prevented because the surface of the underlying layer is sufficiently flattened.

The formation of the dummy trenches on the open region where no or few real interconnects exist also prevents the dishing in the open region.

In the present invention, the plated film growth on the trench is increased with the higher aspect ratio thereof to form a larger thickness. Especially in the region having the crowded patterns, the thicker formation of the plating such as copper suppresses the erosion by the CMP on the crowded portion.

The above and other objects, features and advantages of the present invention will be more apparent from the following description.

### BRIEF DESCRIPTION OF DRAWINGS

FIGS. 1A to 1C are longitudinal partial sectional views of a semiconductor device sequentially showing a conventional method for fabricating the semiconductor device having damascene interconnects.

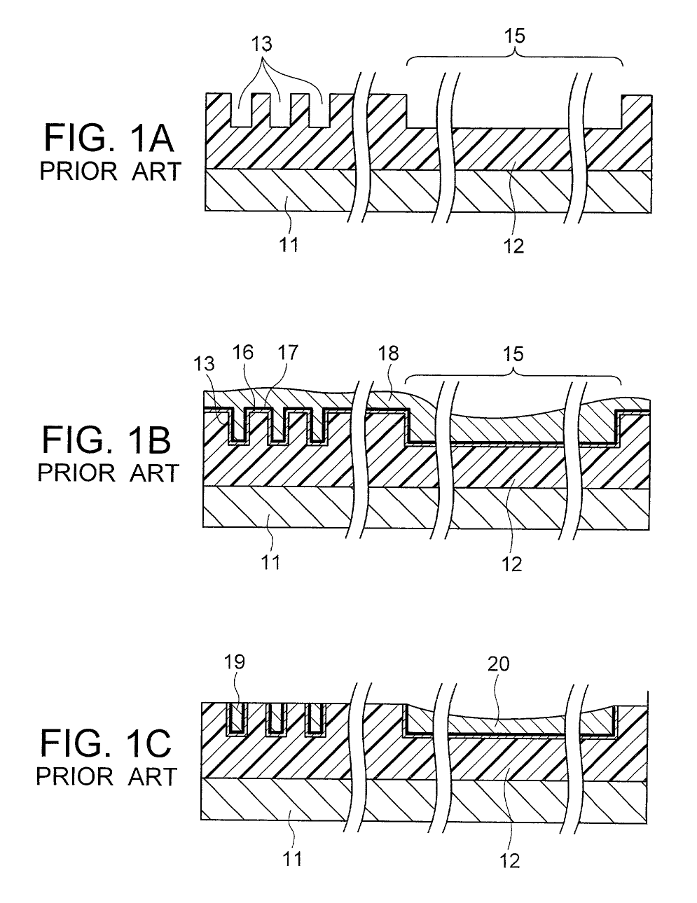

FIGS. 2A to 2C are longitudinal partial sectional views of a semiconductor device sequentially showing a method for fabricating the semiconductor device in accordance with Embodiment 1 of the present invention.

FIG. 3 is a top plan view showing a trench pattern usable in FIGS. 2A to 2C.

FIGS. 4A to 4E are longitudinal partial sectional views of a semiconductor device sequentially showing a method for fabricating the semiconductor device in accordance with Embodiment 2.

FIGS. 5A to 5C are top plan views each showing a trench pattern usable in FIGS. 4A to 4E.

FIGS. 6A to 6E are longitudinal partial sectional views of a semiconductor device sequentially showing a method for fabricating the semiconductor device in accordance with Embodiment 3.

FIGS. 7A to 7C are top plan views each showing a dummy interconnect pattern usable in FIGS. 6A to 6E.

### PREFERRED EMBODIMENTS OF THE INVENTION

Now, the present invention is more specifically described with reference to accompanying drawings.

Embodiment 1

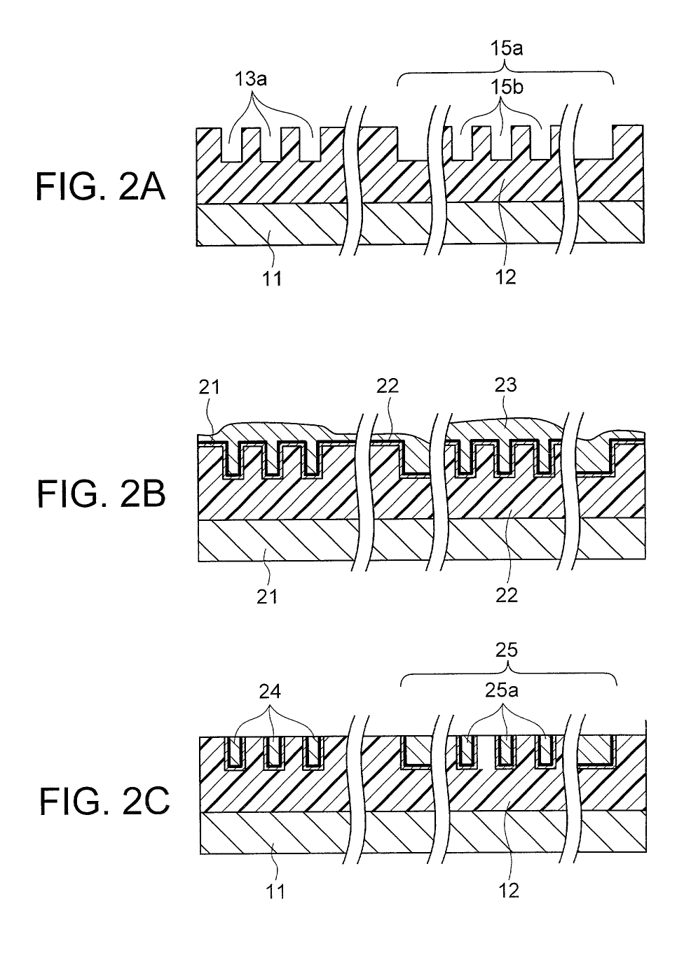

As shown in FIG. 2A, after a dielectric film 12 such as a silicon dioxide (SiO₂) film is formed overlying a semiconductor substrate 11 having device elements (not shown), smaller width trenches 13a having, for example, a trench width of 0.2 μm and arranged with a space of 0.2 μm therebetween and a larger width trench 15a having, for example, a width of 20 μm and a depth of 0.5 μm are formed in the dielectric film 12. This step is conducted by a conventional technique for exposure and anisotropic dry etching which uses, as plasma gas, mixed gas containing CF₄/O₂/Ar and, as a chemically amplified resist, a mask not shown in the drawings. A plurality of slit patterns 15b each having, for example, a trench width of 0.2 μm and a space of 0.2 μm are concurrently formed at the central region of the larger width trench 15a.

After a two-layer film including Ta, TaN or Ta/TaN (TaN is an underlying layer) and a barrier metal film 21 including such as TiN are formed in a thickness of about 50 μm by using sputtering, a film 22 acting as plating seeds made of a metal such as Cu, Ag, or Ni and having a thickness of about 100 nm is deposited on the barrier metal film 21. The film 22 for the plating seeds is used for conducting the plating on the barrier metal film 21 without difficulty.

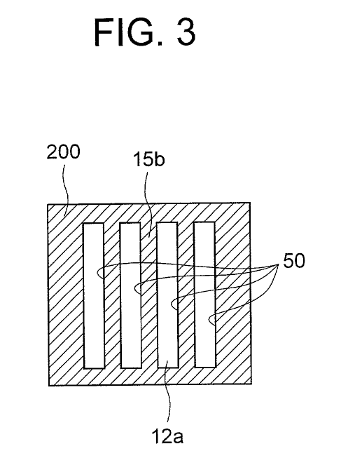

A Cu plated film 23 is deposited thereon by the electroplating technique using a copper sulfate plating solution. The composition thereof includes 100 to 200 g/liter of the copper sulfate (CuSO₄.5H₂0), 50 to 100 g/liter of sulfuric acid (H₂SO₄), 50 to 100 mg/liter of sodium chloride (NaCl) and an organic additive added thereto. The plating is conducted at a liquid temperature between 20 and 30° C. and a cathode current density between 5 and 20 mA/cm². For example, the plating with the current density at the 10 mA/cm² deposits the copper-plating layer at an average rate of 0.22 μm per minute. The organic additive in the copper sulfate plating solution has a function of plating the copper preferentially on the inner surface of the fine trench. More specifically, the organic additive in the copper sulfate plating solution has a function of suppressing the deposition of the plating copper, which hardly enters into the fine trenches, on the substrate other than the fine trenches, thereby increasing the thickness of the copper-plating layer deposited on the inner surface of the fine trench. In the practical example, a copper-plating film 23 having a thickness of about 600 nm could be deposited on the surfaces of the smaller width trenches 13a and the slit patterns 15b whereas a copper plating film 23 having a thickness of about 500 nm was deposited on the substrate other than the trenches (FIG. 2B). As shown in FIG. 3, a plurality of parallel slits 50 for exposing the top surface 12a of the dielectric film are formed in a larger width interconnect section 200.

Thereafter, as shown in FIG. 2C, the copper-plating film 23 and the barrier metal film 21 are polished by using the CMP until the top surface of the dielectric film 12 is exposed to remove portions of the copper-plating film 23, the barrier metal film 21 and the plating seed film 22 other than the interior of the trenches, thereby forming smaller width interconnects 24 and a larger width interconnect 25. Simultaneously, an interconnect slit pattern 25a is formed in the central portion of the larger width interconnect 25.

In the polishing, as shown in FIG. 2B, since the top surface of the copper-plating film 23 on the central portion of the larger width trench 16a is positioned as high as that of the copper-plating film 23 on the smaller width trenches 24, the thickness of the central portion of the larger width trench 15a is not largely decreased when the unnecessary copper-plating film and barrier metal layer are sufficiently removed by using the CMP, thereby preventing the larger increase of the interconnect resistance. When another dielectric film as an overlying layer is formed thereon followed by perforation of via-holes, the connecting deficiency of the via-holes to the larger width interconnect due to the excessive thickness of the underlying dielectric film on the larger width interconnect can be prevented because the surface of the underlying layer is sufficiently flattened.

Embodiment 2

In the present Embodiment, via-holes are formed in a dielectric film on a semiconductor substrate for forming connection with an interconnect layer overlying the semiconductor substrate. The via-holes prevent the dishing of a larger width interconnect during the CMP, and further suppress the increase of the electric resistance of the larger width interconnect when compared with Embodiment 1.

After a dielectric film such as a silicon dioxide (SiO₂) film having a specified thickness is formed overlying a semiconductor substrate 11, an interconnect 26 is formed on the surface of the substrate 11 and another dielectric layer is deposited thereon and the surface of the dielectric layer is flattened.

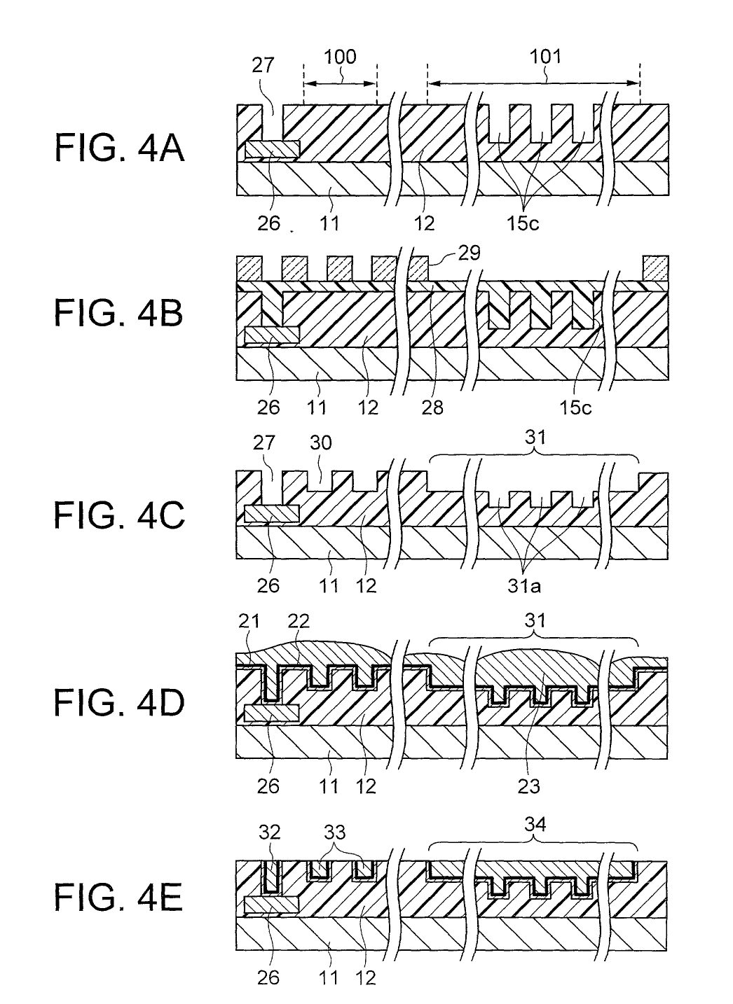

Then, as shown in FIG. 4A, an opening 27 for forming a via-hole having a diameter of about 0.2 μm reaching to the interconnect 26 is formed by using anisotropic dry etching which uses, as plasma gas, mixed gas containing CF₄/O₂/Ar and, as a chemically amplified resist, a mask not shown in the drawings. Simultaneously, a trench pattern 15c is formed having, for example, a trench width of 0.2 μm, a space of 0.2 μm and a depth of about 1 μm at the central region of a larger width trench region 101 having a width of about 20 μm.

As shown in FIG. 4B, after a non-photosensitive organic applied layer 28 (also referred to as “reflection prevention layer”) having a thickness of about 200 nm is formed on the surface of the dielectric film 11 including the interiors of the opening 27 and the trench pattern 15c by applying a raw material of the organic applied layer 28, a photoresist 29 is patterned thereon.

Then, a part of the organic applied layer 28 on the surface of the substrate is etched and removed by using the photoresist 29, as a mask, and mixed plasma gas containing CF₄/O₂/Ar having a total pressure of 400 mtorr. and the respective flow volumes of 15 sccm, 15 sccm and 100 sccm in this turn. After the dielectric film 12 and the organic applied layer 28 are etched by using the photoresist 29, as a mask, and mixed plasma gas containing CF₄/Ar having a total pressure of 400 mtorr. and the respective flow volumes of 100 sccm and 500 sccm in this turn, the photoresist 29 and the organic applied layer 28 existing under the photoresist 29 are removed, thereby forming, in addition to the opening 27, smaller width trenches 30 and a larger width trench 31 in the dielectric film 12. A trench pattern 31a is formed on the central region of the larger width trench region 101, and the height of the top surface of the larger width trench 31 is lower than that of the smaller width trenches 30.

Then, as shown in FIG. 4D and similarly to Embodiment 1, after a stacked film including Ta, TaN or Ta/TaN (TaN is an underlying layer) and a barrier metal film 21 including such as TiN are formed by a thickness of about 50 μm by using sputtering, a film 22 acting as a plating seed made of a metal such as Cu having a thickness of about 100 nm is consecutively deposited on the barrier metal film 21.

A copper-plating film 23 is deposited thereon by the electroplating using a copper sulfate plating solution similarly to Embodiment 1.

Then, as shown in FIG. 4E, the copper-plating film 23 and the barrier metal film 21 are polished by using the CMP until the top surface of the dielectric film 12 is exposed to remove portions of the copper-plating film 23, the barrier metal film 21 and the plating seed film 22 other than the interior of the opening 27 and the trenches, thereby forming a via-hole 32, smaller width interconnects 33 and a larger width interconnect 34.

In the polishing, as shown in FIG. 4D, since the top surface of the copper-plating film 23 on the central portion of the larger width trench 31 is positioned as high as to that of the copper-plating film 23 on the smaller width trenches 30, the thickness of the central portion of the larger width trench 31 is not largely decreased when the unnecessary copper-plating film and barrier metal layer are sufficiently removed by using the CMP, thereby preventing the larger increase of the interconnect resistance. The surface of the larger width interconnect 34 is continuous, thereby suppressing the increase of the electric resistance of the larger width interconnect 34 more efficiently than in Embodiment 1. The connection with an overlying interconnect layer is also easily conducted.

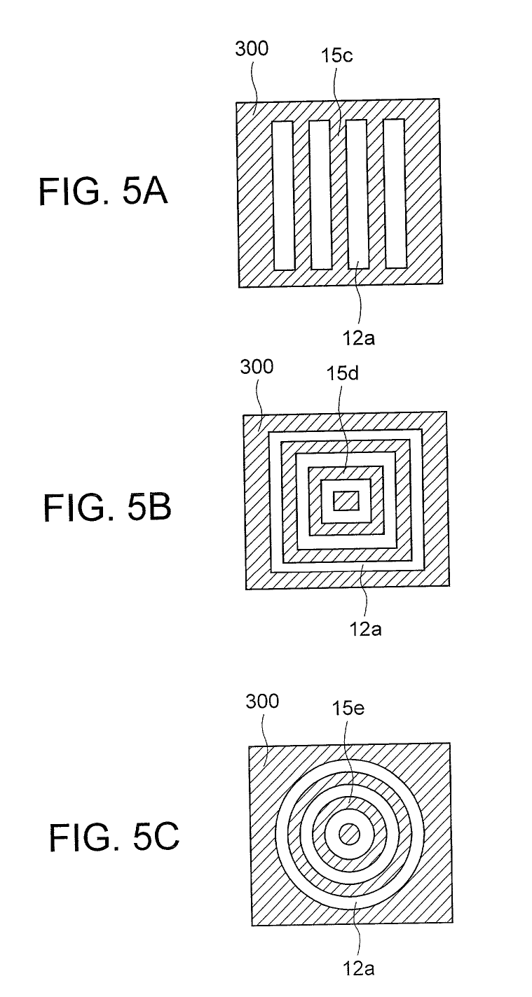

The trench pattern formed on the central region of the larger width trench region 101 in a larger width trench section 300 of FIG. 4A is shown in FIG. 5A. The trench pattern of FIG. 5A includes a plurality of striped slits for exposing the top surface of the dielectric film 12a. In addition, another trench pattern 15d having a plurality of coaxial rectangular striped slits as shown in FIG. 5B or a further trench pattern having a plurality of coaxial annular striped slits as shown in FIG. 5C may be used. A trench pattern having polygonal slits such as triangle slits or pentagonal slits other than the rectangular slits shown in FIG. 5B may be used.

In the trench patterns shown in FIGS. 5B and 5C, the thickness of the electroplated film at the central portion can be thicker than that shown in FIG. 5A. Accordingly, the effect of suppressing the decrease of the film thickness of the central portion of the larger width trench due to the CMP in FIGS. 5B and 5C is higher than that in FIG. 5A.

Embodiment 3

In the present Embodiment, when the density of damascene interconnects formed in a dielectric layer on a semiconductor substrate is uneven, dummy trenches are formed in a region having a reduced density to prevent the dishing of the dielectric film in the reduced density region due to the CMP.

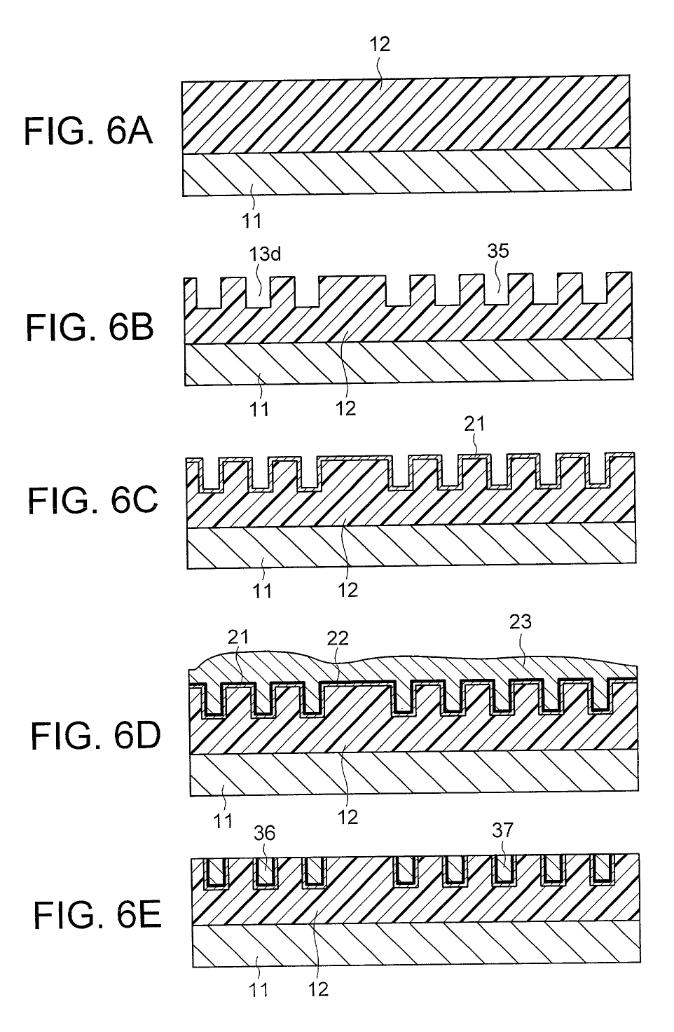

As shown in FIG. 6A, at first, a dielectric film 12 made of SiO₂ is formed on a semiconductor substrate 11.

Then, as shown in FIG. 6B, real interconnect trenches 13d having, for example, a trench width of 0.2 μM, a space of 0.2 μm and a depth of 0.5 μm are formed in the dielectric film 12 by using a conventional method for exposure and anisotropic dry etching which uses, as plasma gas, mixed gas containing CF₄/O₂/Ar and, as a chemically amplified resist, a mask not shown in the drawings. When a broad dielectric film region adjacent to the real interconnect trenches 13d includes no real interconnects, dummy interconnect trenches 35 are formed in the broad region concurrently with the real interconnect trenches 13d after formation of a copper-plating film on the real interconnect trenches 13d for preventing the dishing of the surface of the dielectric film having no interconnects due to the CMP. For example, a trench pattern having a trench width of 0.2 μm, a space of 0.2 μm and a depth of 0.5 μm is formed in a hound's tooth fashion at a suitable interval in a square region having a side of 5 μm.

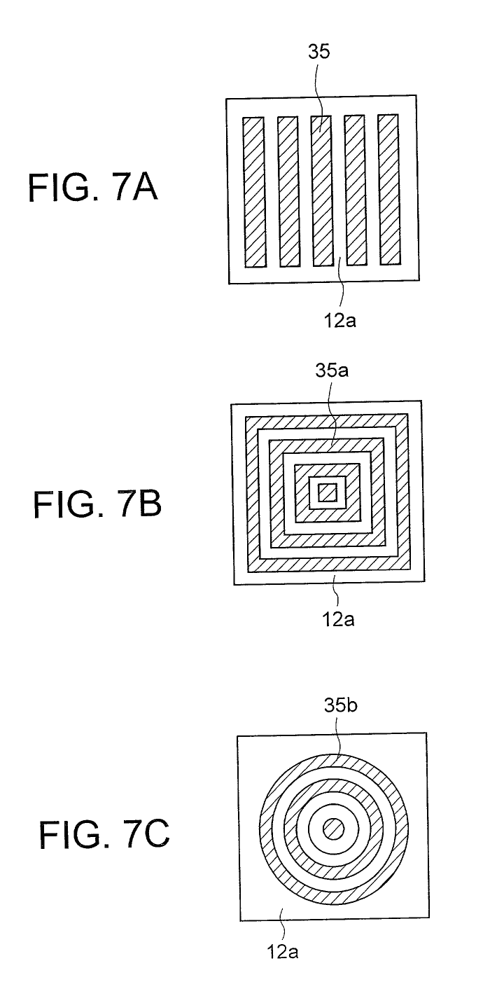

The pattern of the dummy interconnect trenches 35 is exemplified in FIG. 7A. In addition to the pattern having the striped trenches shown therein, another pattern having a plurality of coaxial rectangular striped trenches 35a as shown in FIG. 7B or a further pattern having a plurality of coaxial annular striped trenches 35b as shown in FIG. 7C may be used. A pattern having polygonal trenches such as triangle trenches or pentagonal trenches other than the rectangular trenches shown in FIG. 7B may be used.

Then, as shown in FIG. 6C similarly to Embodiment 1, a stacked film including Ta, TaN or Ta/TaN and a barrier metal film 21 including such as TiN are formed in a thickness of about 50 μm by using sputtering.

As shown in FIG. 6D, after a film 22 acting as a plating seed made of a metal such as Cu and having a thickness of about 100 nm is deposited on the barrier metal film 21, a copper-plating film 23 is deposited thereon by the electroplating using the same copper sulfate plating solution as that of Embodiment 1.

Thereafter, the copper-plating film 23 and the barrier metal film 21 are polished until the top surface of the dielectric film 12 is exposed to remove portions of the copper-plating film 23 and the barrier metal film 21 other than those in the trenches to form real damascene interconnects 36 and dummy damascene interconnects 37. The dummy damascene interconnects 37 formed in the region adjacent to the real damascene interconnects 36 suppress the dishing in this region during the formation of the real damascene interconnects 36 by using the CMP.

Since the above embodiments are described only for examples, the present invention is not limited to the above embodiments and various modifications or alterations can be easily made therefrom by those skilled in the art without departing from the scope of the present invention.

What is claimed is:

1. A method for fabricating a semiconductor device comprising the steps of:
forming a first trench and a second trench in a surface of a dielectric film, the second trench having a width larger than a width of the first trench and having therein a slit wall extending along the second trench on a bottom of the second trench:
depositing a conductive layer on the dielectric film including the first and second trenches; and
polishing the conductive layer until a surface of the dielectric film is exposed, to leave the conductive layer in the first and second trenches as interconnect layers.

2. The method as defined in claim 1, wherein the slit wall has a height equal to a depth of the second trench.

3. The method as defined in claim 1, wherein the conductive layer is deposited by electroplating using a copper sulfate plating solution.

4. The method as defined in claim 1 further comprising the step of sequentially depositing a barrier metal film and a plating seed film before the conductive layer depositing step.

5. The method as defined in claim 4, wherein the barrier metal film is selected from the group consisting of a Ta film, a TaN film and a stacked film including Ta and underlying TaN.

6. The method as defined in claim 4, wherein the plating seed film is formed by a metal selected from the group consisting of Cu, Ag, Au and Ni.

7. The method as defined in claim 1, wherein the slit pattern includes a striped shape.

8. A method of fabricating a semiconductor device comprising the steps of:
forming a first trench and a second trench having a width larger than a width of the first trench in a dielectric film overlying a semiconductor substrate after a trench pattern having a depth larger than that of the first trench is formed at a central portion of the second trench;
depositing a conductive layer on the dielectric film including the first and the second trenches and the trench pattern; and
polishing the conductive layer until a surface of the dielectric film is exposed by using a chemical-mechanical polishing to leave the conductive layer in the first and the second trenches and the trench pattern, thereby forming a damascene interconnect structure on the surface of the dielectric layer.

9. The method as defined in claim 8, wherein the trench pattern includes a striped shape, a coaxial polygonal (not less than triangular) shape and a coaxial annular shape.

10. A method of fabricating a semiconductor device comprising the steps of:
forming a first trench in a dielectric film overlying a semiconductor substrate and a plurality of dummy trenches having specified length, width and spacing on an open region;
depositing a conductive layer on the dielectric film including the first trench and the dummy trenches; and
polishing the conductive layer until a surface of the dielectric film is exposed by using a chemical-mechanical polishing to leave the conductive layer in the first trench and the dummy trenches, thereby forming a damascene interconnect structure on the surface of the dielectric layer.

11. The method as defined in claim 10, wherein the dummy trenches form a pattern including a striped shape, a coaxial polygonal (not less than triangular) shape and a coaxial annular shape.
